(19) United States
(12) Patent Application Publication
(10) Pub. No.: US 2005/0104628 A1
(43) Pub. Date: May 19, 2005

(54) Signal level detector and amplification factor control system using signal level detector

(76) Inventors: Toru Tanzawa, Tokyo (JP); Mototsugu Hamada, (US)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/763,174

(22) Filed: Jan. 26, 2004

(30) Foreign Application Priority Data
Nov. 18, 2003 (JP) 2003-388077

(51) Int. Cl. H03K 5/22

(52) U.S. Cl. 327/63

(57) ABSTRACT

A signal level detector comprises a first voltage/current conversion circuit which outputs a first current which depends on a voltage amplitude of an inputted signal, a second voltage/current conversion circuit which outputs a second current which depends on an inputted reference voltage signal, and a comparison circuit which compares the first current with the second current and outputs an output current based on a comparison result.

### CROSS-REFERENCE TO RELATED APPLICATIONS

This application is based upon and claims the benefit of priority from the prior Japanese Patent Application No. 2003-388077, filed Nov. 18, 2003, the entire contents of which are incorporated herein by reference.

### BACKGROUND OF THE INVENTION

1. Field of the Invention

The present invention relates to a signal level detector for use in a wireless communication integrated circuit system and an amplification factor control system using this signal level detector. For example, the present invention relates to a signal level detector using a circuit which outputs a current which depends on an input voltage amplitude, and an amplification factor control system using this signal level detector.

2. Description of the Related Art

Although an integrated circuit device is in heavy usage in wireless communication, FIG. 1 shows a block diagram of a Bluetooth LSI (15) used in a transceiver system as an example. The LSI 15 is constituted of an RF block 14 and a base band control circuit 13 composed of a digital circuit, a memory and so forth.

Electric waves inputted from an antenna 1 are fetched into the RF block 14 in the LSI 15 through an RF-Filter 2 which transmits only a desired frequency band therethrough. A signal level of a fetched signal is amplified by a low noise amplifier LNA 4 through a Switch 3.

An amplified RF signal is down-converted into an intermediate frequency IF by using a local LO signal of a voltage controlled oscillation circuit VCO 10 through a mixer MIX 5. A band-pass filter BPF 6 transmits only a channel frequency in the IF signal therethrough.

A gain control amplifier GCA 7 controls a signal amplitude in such a manner that this amplitude falls within a dynamic range of an analog-to-digital converter ADC 8. A digital signal sampled by the ADC 8 is transmitted to the base band control circuit 13 which performs base band processing, and demodulated in this circuit.

In transmission of data, the base band control circuit 13 transfers digital data to a Gausian low-pass filter G-fil 12, and the G-fil 12 suppresses a high-frequency component in the digital signal. The VCO 10 is previously set to a predetermined frequency by a phase locked loop PLL 11. An output from the G-fil 12 is supplied to a modulation terminal of the VCO 10, and used to perform frequency modulation with respect to a VCO output frequency. A modulated signal is amplified to a desired power by a power amplifier PA 9, and transferred to the antenna 1 through the switch 3 and the RF-Filter 2 for transmission.

In the wireless communication system, since an intensity of electric waves largely fluctuates in accordance with a distance between a transmitter and a receiver, a mechanism which adjusts an amplification factor in accordance with a received signal level and stabilizes a signal level has been conventionally used in a receiver.

In FIG. 1, a detector DET 16 supplies a signal which depends on a signal level of an output from the MIX 5 to the LNA 4 and applies feedback in such a manner that a gain of the LNA 4 has an appropriate value. Such a system is described in, e.g., ISSCC Digest of Technical Papers, pp. 94-95, February 2003.

Further, the detail of the conventional detector is described in, e.g., IEEE Journal of Solid-state circuits, Vol. 28, No. 1, pp. 78-83, January 1993. In this cited reference, a circuit which generates a current which is in proportion to a square of an amplitude of an input signal (squaring circuit) is used for the detector.

In more detail, two pairs of transistors are used, each pair of transistors with different gate width/length ratios (W/L) being connected at their sources. Two pairs of input terminals (gates) are cross-coupled, and two output terminals (drains) are connected in parallel. Their output current varies depending on a ratio K of W/L of the gate of each of the two transistors, a transistor parameter such as a transconductance parameter β, or an operating current I0 of the circuit. It is to be noted that the transconductance parameter β is in inverse proportion to a 3/2 square of an absolute temperature.

The detector simply using a squaring circuit in this manner has a problem that the stable detection cannot be performed because the detector includes the circuit/device parameter dependence or the temperature dependence.

As described above, a mechanism which adjusts an amplification factor in accordance with a received signal level and stabilizes a signal level has been conventionally used in a radio receiver. However, this stabilization mechanism has the device parameter dependence or the temperature dependence. Therefore, the signal level obtained by amplifying the received signal has the large device parameter dependence or temperature dependence.

Thus, realization of a signal level detector which does not have the circuit/device parameter dependence or the temperature dependence and an amplification factor control system using this detector has been demanded.

### BRIEF SUMMARY OF THE INVENTION

According to a first aspect of the invention, there is provided is a signal level detector, which comprises:
a first voltage/current conversion circuit which outputs a first current which depends on a voltage amplitude of an inputted signal;
a second voltage/current conversion circuit which outputs a second current which depends on an inputted reference voltage signal; and
a comparison circuit which compares the first current with the second current and outputs an output current based on a comparison result.

According a second aspect of the invention, there is provided a signal level detector, which comprises:
a first squaring circuit to which a first voltage signal is inputted and which outputs a first current including a square component of an input amplitude of the first voltage signal;
a second squaring circuit to which a reference voltage signal is inputted and which outputs a second current including a square component of an amplitude of the reference voltage signal; and
a comparison circuit which compares a first output voltage which is in proportion to the first current with a second output voltage which is in proportion to the second current, and outputs a control signal used to detect the first voltage signal based on a comparison result.

According to a third aspect of the invention, there is provided an amplification factor control system, which comprises:
a signal level detector which includes a first voltage/current conversion circuit which outputs a first current which depends on a voltage amplitude of an inputted signal, a second voltage/current conversion circuit which outputs a second current which depends on an inputted reference voltage signal, and a comparison circuit which compares the first current with the second current and outputs a control signal based on a comparison result; and
an amplification circuit to which the control signal of the signal level detector is inputted, and which outputs an output signal obtained by amplifying an inputted reception signal with an amplification factor according to the control signal and determines the output signal as the detection signal which is inputted to the signal level detector.

### BRIEF DESCRIPTION OF THE SEVERAL VIEWS OF THE DRAWING

FIG. 1 is a block diagram showing a structure of a transceiver LSI as an example of a conventional wireless integrated circuit device;

FIG. 2 is a block diagram illustrating a concept of a signal level detector which is in common with embodiments according to the present invention;

FIG. 3 is a block diagram illustrating a concept of an amplification factor control system which is in common with the embodiments according to the present invention;

FIG. 4 is a circuit diagram showing a detector according to a first embodiment;

FIG. 5 is a circuit diagram of an amplification circuit used in the first to third embodiments;

FIG. 6 is a circuit diagram of a charging type squaring circuit used in the first embodiment;

FIG. 7 shows a circuit which generates an nbias signal in FIG. 5;

FIG. 8 is a circuit diagram illustrating an operation of the squaring circuit used in the embodiments according to the present invention;

FIG. 9 is a waveform diagram illustrating an operation within an operation range of an amplification factor control system according to the present invention;

FIG. 10 is a waveform diagram illustrating an operation out of the operation range of the amplification factor control system according to the present invention (when an input power is small);

FIG. 11A is a graph showing a relationship between an input power and a control signal in the amplification factor control system according to the present invention;

FIG. 11B is a graph showing a relationship between an input power and an output power in the amplification factor control system according to the present invention;

FIG. 12 is a circuit diagram showing a discharging type squaring circuit which can be used in place of the charging type squaring circuit in the first embodiment;

FIG. 13 is a circuit diagram of a detector according to a second embodiment;

FIG. 14 is a circuit diagram showing a charging type squaring circuit used for the detector depicted in FIG. 13;

FIG. 15 is a circuit diagram showing a discharging type squaring circuit used for the detector depicted in FIG. 13;

FIG. 16 is a circuit diagram of a modification of the detector according to the second embodiment, showing an example that the charging type and the discharging type are counterchanged;

FIG. 17 is a circuit diagram of a reference voltage circuit having a very small temperature coefficient which is used in the second embodiment;

FIG. 18 is a circuit diagram of a detector according to a third embodiment;

FIG. 19 is a circuit diagram of a detector according to a modification of the third embodiment; and

FIG. 20 is a circuit diagram of an amplification circuit used in combination with a modification of FIG. 19.

### DETAILED DESCRIPTION OF THE INVENTION

According to embodiments described below, since an output from a voltage/current conversion circuit (e.g., a squaring circuit) to which a received signal is inputted is compared with an output from a voltage/current conversion circuit (e.g., a squaring circuit) to which a reference voltage is inputted in order to detect a level of the received signal, the relatively stable level detection can be performed even if the voltage/current conversion circuit (squaring circuit) has variations in temperature characteristics or product properties.

Furthermore, in an amplification factor control system using a signal level detector according to this embodiment, since it is possible to perform the control with the small temperature dependence, the temperature dependence of the reception sensitivity can be suppressed. Moreover, the system hardly affected by manufacturing variations, thereby improving a yield ratio.

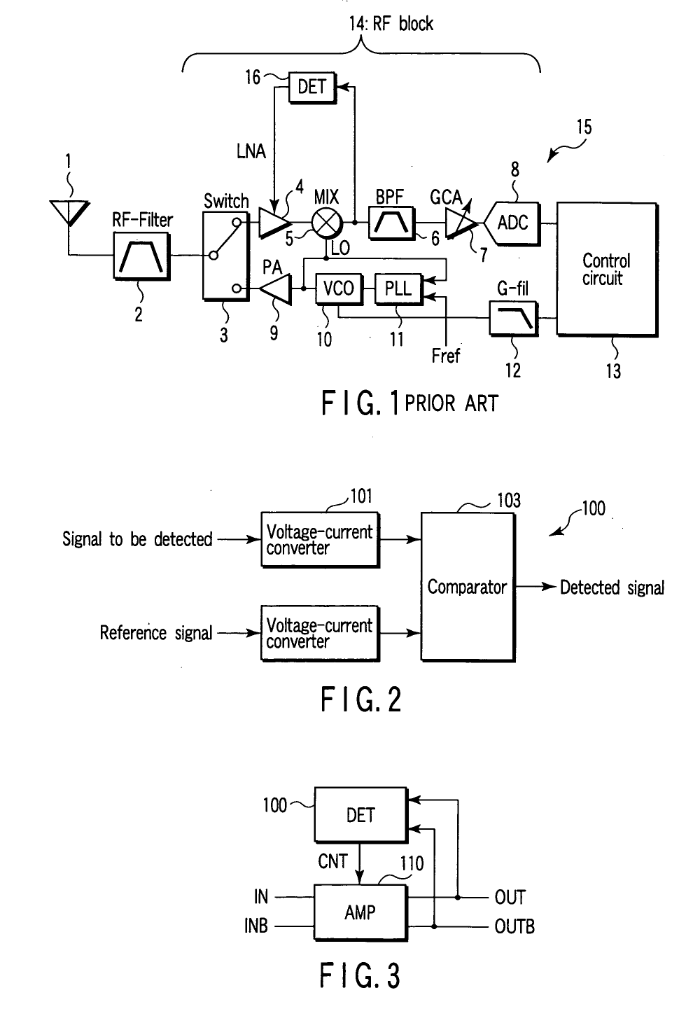

FIG. 2 is a block diagram showing a basic structure of a signal level detector 100 which is common with the embodiments mentioned below. A signal to be detected and a reference signal are respectively inputted to two voltage/current conversion circuits (e.g., squaring circuits) 101 and 102, outputs from the two voltage/current conversion circuits are inputted to a comparison circuit (e.g., a differential amplifier) 103, and a comparison (amplification) signal which depends on a potential difference between the two inputs is outputted. Therefore, even if the respective voltage/current conversion circuits 101 and 102 have the bias current dependence of a transistor parameter or a circuit, outputs from these two circuits are affected by the same factor. Amplifying a relative difference between them can eliminate their parameter dependence from detection signals to be outputted, thereby performing the stable signal level detection.

FIG. 3 is a block diagram showing a configuration of the signal level detector (DET) 100 in an RF block, and an input signal IN and its reverse signal INB are inputted to an amplification circuit (AMP) 110. An output signal OUT and its reverse signal OUTB from the AMP 110 are inputted to the DET 100, and the DET 100 outputs a feedback signal (control signal) CNT to the AMP 110, thereby stabilizing OUT and OUTB.

Concrete embodiments of the detector and the amplification factor control system will now be described hereinafter.

### First Embodiment

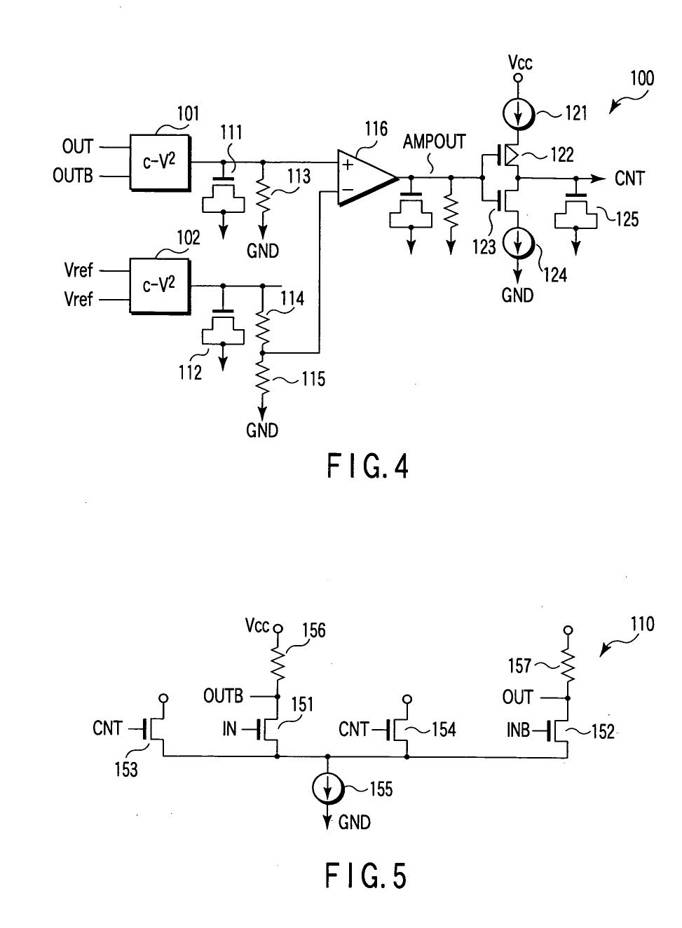

FIG. 4 shows a signal level detection according to the first embodiment of the present invention. Differential signals OUT and OUTB are inputted to a first squaring circuit 101, and an output from this circuit is inputted to one input terminal of a differential amplifier 116 as a comparison circuit. A capacitance element 111 and a resistor 113 are connected between an output terminal of the first squaring circuit 101 and a ground terminal (GND). The capacitance element 111 is inserted in order to filter a second harmonic component in an input signal.

The same reference voltages Vref are inputted to two input terminals of a second squaring circuit 102, an output current from this circuit is converted into a voltage by resistance elements 114 and 115, and a divided voltage is inputted to the other input terminal of the differential amplifier 116. A capacitance element 112 is also connected between an output terminal of the second squaring circuit 101 and the ground in order to filter a second harmonic component in an input signal.

An output voltage AMPOUT from the differential amplifier 116 is inputted to a common gate of an output stage that a p channel side constant current source 121, a p channel transistor 122, an n channel transistor 123 and an n channel side constant current source 124 are connected between a power supply terminal Vcc and the GND in series, and a control signal CNT is outputted from a connection node (drain) between the p channel transistor 122 and the n channel transistor 123.

A capacitance element 125 is connected between a CNT terminal and the ground. Since it is desirable for a potential of the CNT terminal to be in the steady state, the capacitance element 125 is inserted in order to stabilize the potential of the CNT terminal.

A voltage Vout1=R×Iout, which is generated from an output current Iout=Itail−bvpp² which depends on a square of an amplitude of the differential signal OUT or OUTB, is outputted from the output terminal of the first squaring circuit 101. In this case, Itail is a bias current, vpp is a voltage amplitude of the differential signal, and R is a resistance value of the resistance element 113. Further, b is a coefficient but it has the temperature dependence as will be described later.

Since reference DC voltages Vref in phase are inputted to the second squaring circuit 102, a voltage Vout2=a R×Iout, which is generated from an output current (bias current) Itail, is outputted from its output terminal. In this case, R is a resistance value of a resistance element 115 when R is a total resistance value of the serially connected resistance elements 114 and 115 (a is a distribution ratio).

AMPOUT which is obtained by comparing and amplifying Vout1=R×Iout and the Vout2=a R×Iout is generated at an output terminal of the differential amplifier 116 as a comparison circuit. The logic of the AMPOUT is reversed when Vout1=Vout2, i.e., at the time of vpp with which vpp²=(1−a)Itail/b is established. Although the coefficient b which is in proportion to the mobility of electrons has the strong temperature dependence, constituting Itail so as to be in proportion to b as will be described later can suppress the device parameter dependence of the detection voltage level.

The control signal CNT is inputted to an AMP 110 shown in FIG. 5. The AMP 110 has n channel transistors 151 and 152 having a gate to which the differential inputs IN and INB are inputted and n channel transistors 153 and 154 having gates to which the control signal CNT is inputted, and sources of these transistors are all grounded through a constant current source 155. Drains of the input transistors 151 and 152 are connected to the power supply terminal Vcc through resistance elements 156 and 157, and further connected to the differential output terminals OUTB and OUT.

As shown in FIG. 3, outputs from the AMP 110 are inputted to the DET 100. In such a structure, a level of the output signal OUT is high when an input signal level of the AMP 110 is high at the time of start of an operation, but an amplification factor of the AMP circuit 110 is lowered, since the output CNT of the DET 100 which receives the output signal OUT is large, thereby weakening its output signal level.

When the input signal level of the AMP 110 is weak, since the reverse of the above is applied, it acts so as to increase the output signal level. As a result, even if the input signal level varies or a temperature variation is large, the output signal with the stable level can be obtained.

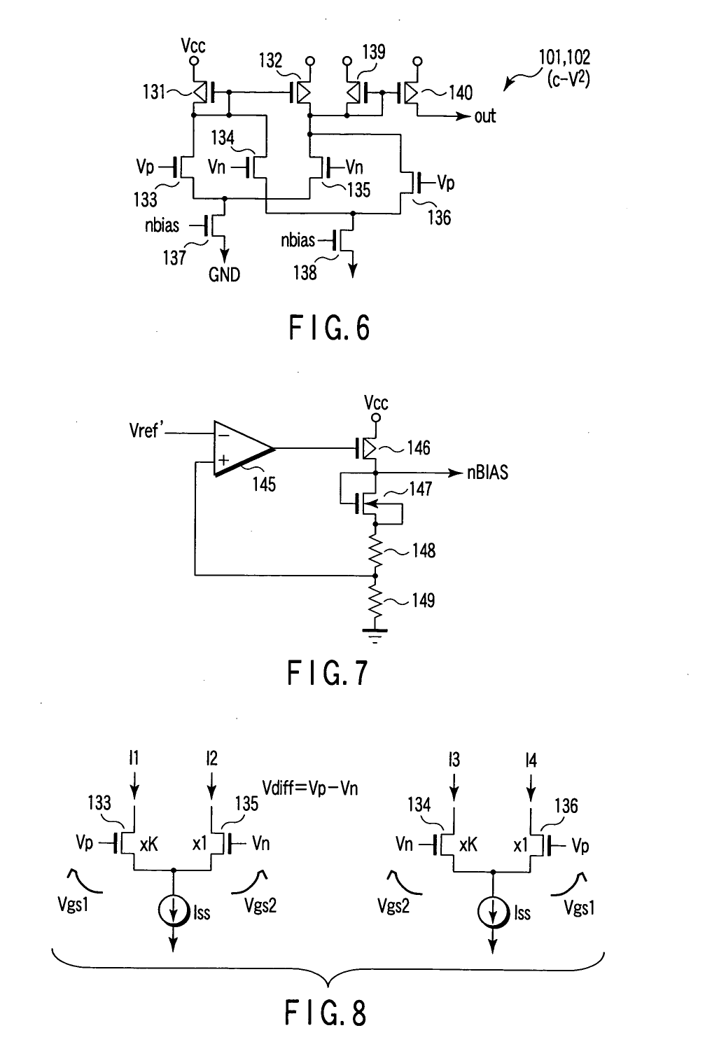

A description will now be given as to a structure of a squaring circuit configured in such a manner that Itail is in proportion to b. A charging current type squaring circuit shown in FIG. 6 is used for the squaring circuit. Gate biases nbias of n channel transistors 137 and 138 shown in FIG. 6 are supplied by a circuit depicted in FIG. 7 and give characteristics that Itail is in proportion with b. It is to be noted that a symbol c-V² is inscribed with respect to the squaring circuits 101 and 102 in FIG. 4 in order to represent that these circuits are of a changing type. This is also applied to the following relevant drawings.

The squaring circuit depicted in FIG. 6 will be first explained. In FIG. 6, a pair of n channel transistors 133 and 135 are source-coupled and connected to an n channel transistor 137 which is a constant current source. Likewise, a pair of n channel transistors 134 and 136 are source-coupled and connected to an n channel transistor 138 which is a constant current source.

Furthermore, drains of the transistors 133 and 134 are connected to a drain and a gate of a p channel transistor 131. Drains of the transistors 135 and 136 are connected to a drain of a p channel transistor 132. Gates of the p channel transistors 131 and 132 are connected to each other and constitute a current mirror circuit.

Moreover, one current output terminal of the pair of p channel transistors 139 and 140 constituting a current mirror circuit is connected to a drain of the transistor 132, and a charging current is outputted from a drain of the transistor 140 which is the other current output terminal. This charging current flows into, e.g., the resistance element 113 shown in FIG. 4 and gives a potential to the input terminal of the differential amplifier 116.

Gate voltages Vp of the transistors 133 and 136 and gate voltages Vn of the transistors 134 and 135 are differential voltages, and Vp and Vn respectively correspond to OUT and OUTB in the example of the squaring circuit 101 depicted in FIG. 4.

Moreover, the two transistors 133 and 135 which are source-coupled are configured to have different gate dimensions. That is, when W is a gate width and L is a gate length, ratios of W/L of the respective two transistors are set to K. Likewise, ratios of W/L of the two source-coupled transistors 134 and 136 are set to K.

FIG. 8 shows an equivalent circuit of cross-coupled transistors. It is assumed that I1, 12, 13 and 14 are drain currents of the transistors 133, 135, 134 and 136, Vdiff (=Vp−Vn) is a differential voltage of the differential inputs Vp and Vn, and Iss is a constant current value. Assuming that W/L of each of the transistors 135 and 136 is 1, the same of each of the transistors 133 and 134 is K.

At this time, a differential current dI of the drain currents I1 and I2 is represented by the following expression.

$$\begin{matrix}dI = I1 - I2 \\ = [ ( K - 1 ) \{ ( K + 1 ) Iss - 2 β {KVdiff}^{2} \} + \\ 4 β {KVdiff [ ( K + 1 ) Iss / β - {Kvdiff}^{2} ]}^{0.5} / {( K + 1 )}^{2}\end{matrix} \qquad ( 1 )$$

Additionally, a total output current dItot is represented by the following expression.

$$\begin{matrix}dItot = ( I1 - I2 ) + ( I3 - I4 ) \\ = dI ( + Vdiff ) + dI ( - Vdiff ) \\ = 2 ( K - 1 ) / ( K + 1 ) Iss - 4 ( K - 1 ) β K / {( K + 1 )}^{2} {Vdiff}^{2}\end{matrix} \qquad ( 2 )$$

When Vdiff=Vppcoswt, the following expression can be obtained, wherein the symbol ≈ means “nearly equal”.
dItot≈2(K−l)/(K+1)(Iss−βK/(K+1)Vpp²)+O(cos(2wt)) (3)
When a low-pass filter is inserted to the output terminal, a term of 2wt is filtered and only DC of the first term is outputted, an output signal which is in proportion to a square of a voltage amplitude of an input signal can be obtained. The capacitance elements 111 and 112 shown in FIG. 4 are provided for this purpose.

It is to be noted that β in the above expression is a transconductance parameter. Further, the first term 2(K−1)/(K+1)Iss in the mathematical expression decomposed by resolving the parenthesis in the first term corresponds to Itail mentioned above, and 2(K−1)/(K+1)βK/(K+1) corresponds to b. It is to be noted that β is in inverse proportion to a 3/2 square of an absolute temperature.

A method of constituting in such a manner that Itail is in proportion to b will now be described. As mentioned above, FIG. 7 shows a circuit which gives gate biases of the transistors 137 and 138 depicted in FIG. 6. A p channel transistor 146, an n channel transistor 147 and resistance elements 148 and 149 are connected in series between Vcc and GND, and a gate of the p channel transistor is connected to an output terminal of a differential amplifier 145. A predetermined reference voltage Vref′ is connected to a minus input terminal of the differential amplifier 145, and a plus input terminal of the same is connected to a connection node between the resistance elements 148 and 149. This Vref′ may be or may not be the same as Vref in FIG. 4.

When a ratio A of the resistance elements 148 and 149 is determined in such a manner that a source potential of the n channel transistor 147 becomes AVref′ and a threshold value of the transistor 147 is Vth, nBIAS=AVref+Vth is achieved. Since the n channel transistor which receives this passes Itail=b(nBIAS−Vth)²=bA²Vref′² as a saturation current, Itail can be in proportion to b.

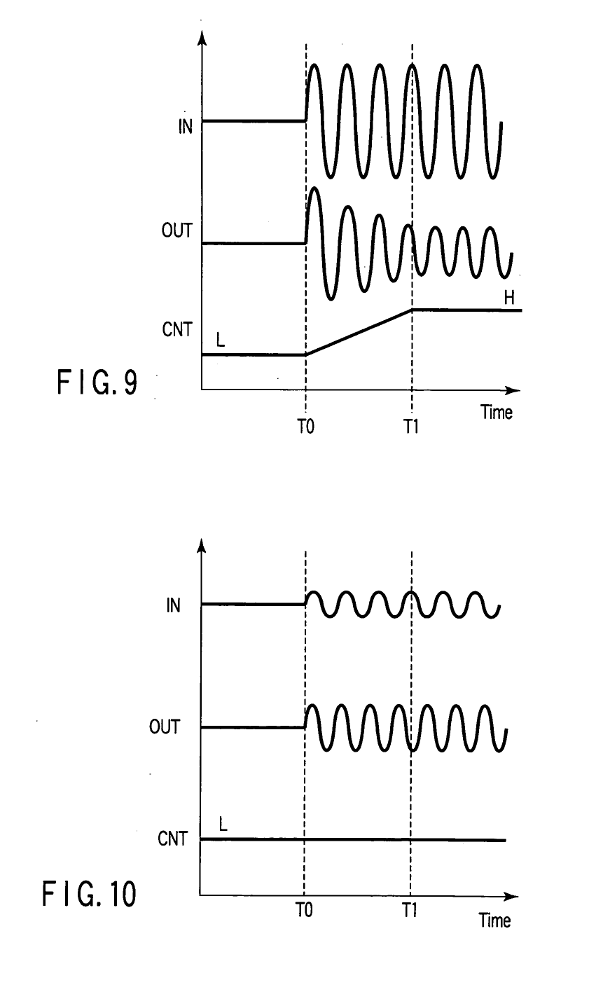

Here, an operation of the circuit shown in FIG. 4 will now be described. FIGS. 9 and 10 show operating waveforms. Furthermore, FIG. 11A shows a relationship between a power P (IN) of the input signal and the control signal CNT. When the input power P (IN) is in a range of P1 to P2, the control signal which is in proportion to the input power is outputted and a control operation is executed. When the input power P (IN) is not more than P1 or not less than P2, the control signal is a constant output on an “L” level or an “H” level. Moreover, FIG. 11B shows a relationship between the input power P (IN) and an output power P (OUT). When the input power P (IN) is in a range of P1 to P2, since the control operation is executed, a constant output power P (OUT) is outputted. When the input power P (IN) is not more than P1 or not less than P2, the output power P (OUT) which is in proportion to the input power P (IN) is outputted.

As described above, the control operation is effectively executed when the input power P (IN) is in the range of P1 to P2 shown in FIGS. 11A and 11B. FIG. 9 shows waveforms of the input signal IN, the output signal OUT and the control signal CNT when the input power is P1 to P2. This drawing shows a state that an amplitude of OUT is decreased as CNT is increased from a time T0 to a time T1 and it is controlled to a desired amplitude. That is, when the input power exceeds a reference value P1, CNT applies a feedback in such a manner that the output power P (OUT) becomes constant.

FIG. 10 shows a case that the input power P (IN)<P1. Since the input power P (IN) is small, CNT is in an “L” state so as to obtain a maximum state of a gain of the amplifier. When the input power P (IN) is not less than P2, CNT fully exerts the maximum level “H”, and the output power P (OUT) is again increased.

It is to be noted that the squaring circuit according to this embodiment is not restricted to the charging type shown in FIG. 6, and it may be of a discharging type. In this case, in the DET 100, one end of the resistance terminals 113 and 115 must be pulled up to Vcc instead of being pulled down to GND.

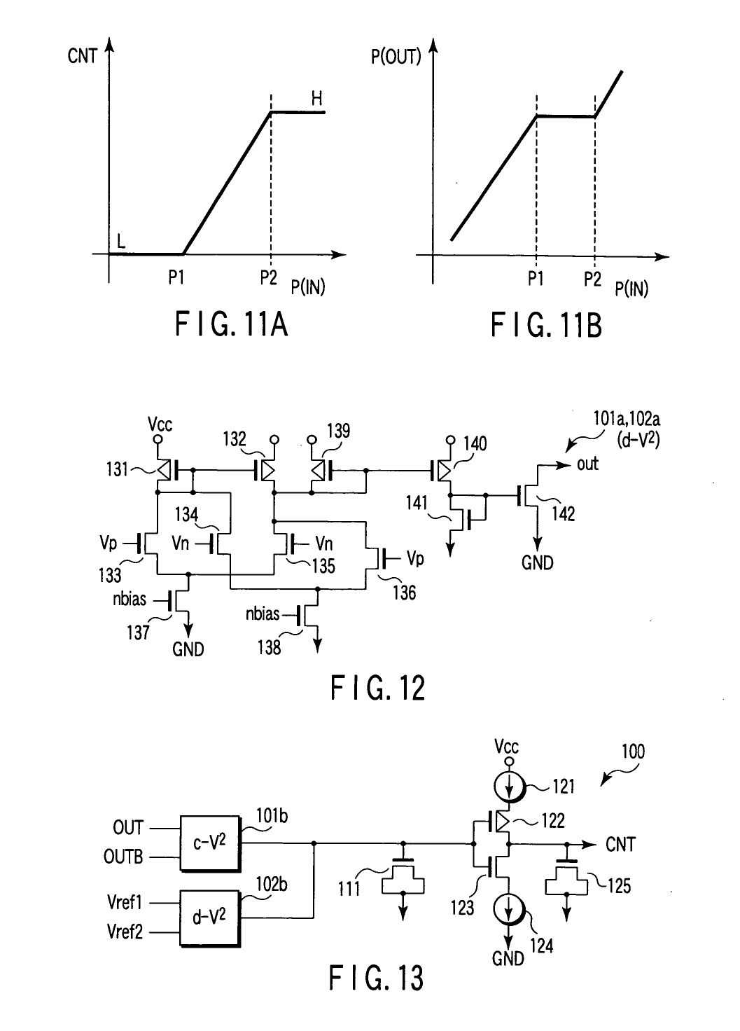

FIG. 12 shows a circuit configuration of discharging type squaring circuits 101a and 102a which are used instead of the charging type squaring circuits 101 and 102 depicted in FIG. 4. Since they are similar to the charging type circuits illustrated in FIG. 6, like reference numerals denote the same parts, thereby eliminating tautological explanation. FIG. 12 is different from FIG. 6 in that n channel transistors 141 and 142 constituting a mirror circuit are added to a drain of a p channel transistor 140 at the output end so that a current inflows from an output terminal out. This current inflows from Vcc through, e.g., the resistance element 113 and gives a potential to the input terminal of the differential amplifier 116.

Gate biases nbias of the transistors 137 and 138 shown in FIG. 12 are given by the circuit depicted in FIG. 7. In this manner, the same detection operation as that in FIG. 4 can be performed.

### Second Embodiment

FIG. 13 shows a signal level detector according to a second embodiment of the present invention. In order to facilitate understanding, like reference numerals denote parts equal to those in the first embodiment. Differential signals OUT and OUTB are inputted to a first squaring circuit 101b, and different reference voltages Vref1 and Vref2 are inputted to two input terminals of a second squaring circuit 102b. Output terminals of the first and second squaring circuits are directly connected to each other, and a capacitance element 111 is connected between the output terminal of these circuits and GND. The capacitance element 111 is inserted in order to filter a double harmonic component in an input signal.

A total output from the first and second squaring circuits is inputted to a common gate of an output stage that a p channel side constant current source 121, a p channel transistor 122, an n channel transistor 123 and an n channel side constant current source 124 are connected in series between Vcc and GND, and a control signal CNT is outputted from a connection node (drain) between the p channel transistor 122 and the n channel transistor 123. A capacitance element 125 for stabilizing an output signal is connected to the CNT terminal.

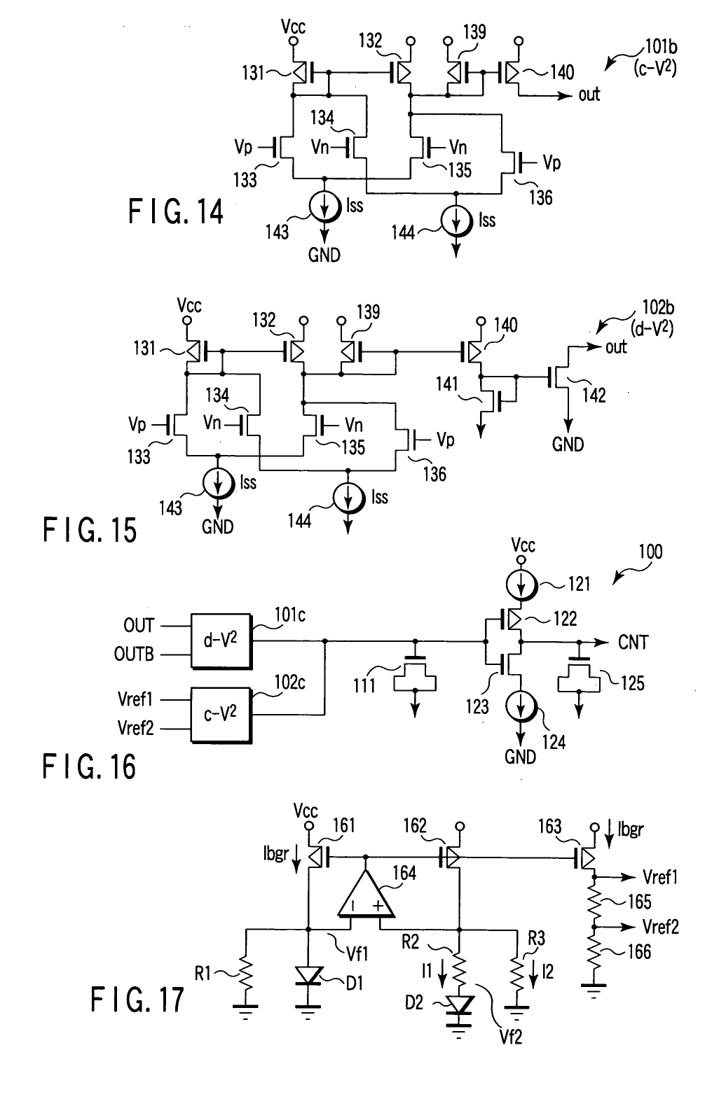

A charging type squaring circuit (c-V²) 101b shown in FIG. 14 is used for the first squaring circuit, and a discharging type squaring circuit (d-V²) 102b illustrated in FIG. 15 is used for the second squaring circuit. Although they are basically the same as 101, 102, 102a and 102b shown in FIGS. 6 and 12, an only difference lies in that the parts of the transistors 137 and 138 are substituted with constant current sources 143 and 144.

Since a total output voltage of the squaring circuits 101b and 102b corresponds to pulling of a discharging current Idis=Itail−bdVref² which depends on a difference dVref between the two reference voltages Vref1 and Vref2 and a charging current Ichar=Itail−bVpp² against each other, the logic of the output voltage is reversed when Idis=Ichar, i.e., vpp=dVref is established. Therefore, although this detection level has the same dependence as the temperature dependence of dVref, using a reference voltage such as a known band gap reference having the very small temperature dependence can readily realize the squaring circuit having the very small temperature dependence.

The same amplifier as that in the first embodiment can be used for the AMP 110, and the control signal CNT is inputted to the AMP 110 shown in FIG. 5 in the first embodiment. By constituting the amplification factor control system in this manner, the same advantages as those in the first embodiment can be demonstrated in the second embodiment.

It is to be noted that the charging type and the discharging type of the two squaring circuits can be counterchanged like FIG. 16 in the structure depicted in FIG. 13. In this case, the circuit configuration shown in FIG. 15 can be used for the discharging type squaring circuit 10c, and the circuit configuration depicted in FIG. 14 can be used for the charging type squaring circuit 102c. However, since the polarity of the output CNT signal is reversed, an amplifier which does the reverse of the operation in FIG. 5 must be used for the amplifier 110. For example, using a later-described amplifier 110a shown in FIG. 20 can suffice.

FIG. 17 shows an example of a reference voltage circuit having a very small temperature coefficient. In this drawing, an area of a diode D2 is set larger than an area of a diode D1. Therefore, a relationship of Vf1>Vf2 is achieved between a forward voltage Vf1 of the diode D1 and a forward voltage Vf2 of the diode D2. Moreover, since the current density of the diode D2 is smaller than the current density of the diode D1 when the same current is passed through them, a temperature coefficient of Vf2 is larger than a temperature coefficient of Vf1. Thus, a temperature coefficient of ΔVf=Vf1−Vf2 is positive.

A cathode of the diode D1 is grounded, and an anode is connected to a power source Vcc through a p channel transistor 161 and also connected to a minus input terminal of a differential amplifier 164. Moreover, an anode of the diode D1 is grounded through a resistance element R1.

A cathode of the diode D2 is grounded, and an anode is connected to the power supply Vcc through a resistance element R2 and a p channel transistor 162. A drain of the transistor 162 is connected to a plus input terminal of the differential amplifier 164 and also grounded through a resistance element R3.

Additionally, as an output stage, a p channel transistor 163 and resistance elements 165 and 166 are connected in series between Vcc and GND. Vref1 can be taken out from a drain of the transistor 163, and Vref2 can be taken out from a connection node between the resistance elements 165 and 166.

Gates of the transistors 161 to 163 are connected to each other and also connected to an output terminal of the differential amplifier 164. Drain currents of the transistors 161 to 163 are all Ibgr, and a feedback is applied to them so that two inputs of the differential amplifier 164 match with each other.

In the above-described setting, a current I1 flowing through the resistance element R2 is I1=(Vf1−Vf2)/R2=ΔVf/R2, and a current I2 flowing through the resistance element R3 is I2=Vf1/R3. Therefore, Igbr=I1+I2=(Vf1+Δvf*R3/R2)/R3.

In the above expression, Vf1 has a negative temperature coefficient, and ΔVf has a positive temperature coefficient as described above. Thus, when R3/R2 is set so as to cancel out their temperature coefficients, a temperature coefficient of the output current Igbr can be set very small. As a result, temperature coefficients of reference voltages Vref1 and Vref2 created based on Igbr also become small.

The reference voltage circuit is not restricted to that shown in FIG. 17, and three resistance elements on the output stage depicted in FIG. 17 may be connected in series and Vref1 and Vref2 may be taken out from the both ends of the central resistance element. Further, the first reference voltage having a very small temperature coefficient may be created, then the second reference voltage may be created through a buffer, and Vref1 and Vref2 may be created by performing resistance division to the output voltage.

Since a bias current (Iss) supply circuit of the squaring circuit is simplified and the differential amplifier is unnecessary in the second embodiment, there is an advantage that the entire circuit configuration is simplified.

### Third Embodiment

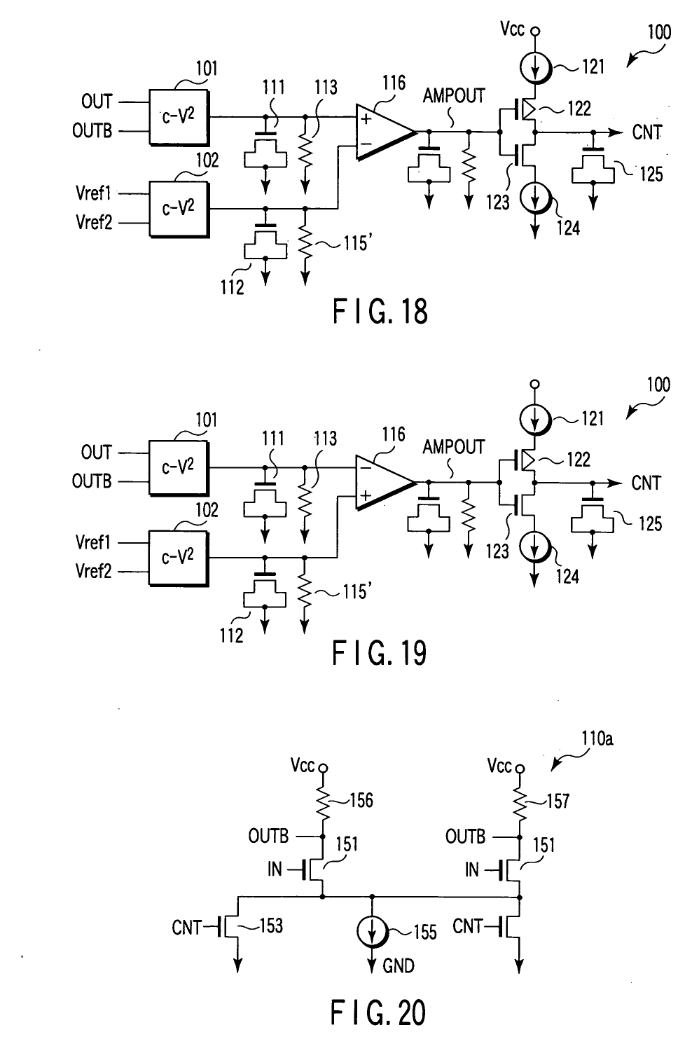

FIG. 18 shows a signal level detector according to the third embodiment of the present invention. Like reference numerals denote parts equal to those in the first and second embodiments, thereby eliminating tautological explanation. Since a second squaring circuit 102 outputs a voltage Vout2=Itail=bdVref² which depends on a difference dVref between two reference voltages Vref1 and Vref2, the logic of AMPOUT is reversed when Vout1=Vout2, i.e., vpp=dVref is established. Therefore, the same advantages as those in the second embodiment can be obtained. It is to be noted that the circuit depicted in FIG. 5 can be used for the AMP 110 used to form an amplification factor control system.

In the circuit configuration shown in FIG. 18, a control signal CNT is also increased as an output voltage OUT of the AMP 110 is increased. The third embodiment is not restricted to such a circuit configuration, and it may have a circuit configuration that the control voltage CNT is decreased as the output voltage OUT of the amplifier is increased.

FIGS. 19 and 20 show circuit examples enabling such a control. Like reference numerals denote parts equal to those in FIGS. 18 and 5, thereby eliminating tautological explanation. However, FIG. 19 shows a differential amplifier whose polarity is reversed from that of the differential amplifier 116 in FIG. 18, and a polarity of an amplifier 110a in FIG. 20 is reversed from a polarity of CNT-gain characteristics of the amplifier 110 in FIG. 5. As a result, the structure of the amplification factor control system shown in FIGS. 19 and 20 is equivalent to that of FIGS. 18 and 5.

Further, as squaring circuits 101 and 102 in the third embodiment, discharging type squaring circuits may be used.

Since a current which is in proportion to a square of a voltage amplitude of the signal OUT or OUTB, which should be detected, are compared with a current which is in proportion to a square of a voltage amplitude of a difference between the reference signals Vref1 and Vref2 by using the differential amplifier, it is possible to output the control signal with the excellent accuracy that an input and an output are separated by the buffer effect.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A signal level detector comprising:
a first voltage/current conversion circuit which outputs a first current which depends on a voltage amplitude of an inputted signal;
a second voltage/current conversion circuit which outputs a second current which depends on an inputted reference voltage signal; and
a comparison circuit which compares the first current with the second current and outputs an output current based on a comparison result.

2. The signal level detector according to claim 1, wherein the inputted signal is a differential signal, and the reference voltage signal includes two reference voltages.

3. The signal level detector according to claim 1, wherein the first voltage/current conversion circuit outputs the first current which depends on a square of a voltage amplitude of the inputted signal, and the second voltage/current conversion circuit outputs the second current which depends on a square of an amplitude of the inputted reference voltage signal.

4. The signal level detector according to claim 1, further comprising a first capacitance element and a second capacitance element respectively connected between an output terminal of the first voltage/current conversion circuit and a ground potential and between an output terminal of the second voltage/current conversion circuit and the ground potential.

5. The signal level detector according to claim 1, further comprising a first resistance element and a second resistance element, respectively connected between an output terminal of the first voltage/current conversion circuit and a ground potential and between an output terminal of the second voltage/current conversion circuit and the ground potential.

6. The signal level detector according to claim 1, wherein an output terminal of the first voltage/current conversion circuit and an output terminal of the second voltage/current conversion circuit are directly connected to each other and form one output end.

7. The signal level detector according to claim 6, wherein the first current is a charging current which flows out from the output terminal, and the second current is a discharging current which flows into the output terminal.

8. The signal level detector according to claim 6, wherein the first current is a discharging current which flows into the output terminal, and the second current is a charging current which flows out from the output terminal.

9. A signal level detector comprising:
a first squaring circuit to which a first voltage signal is inputted and which outputs a first current including a square component of an input amplitude of the first voltage signal;
a second squaring circuit to which a reference voltage signal is inputted and which outputs a second current including a square component of an amplitude of the reference voltage signal; and
a comparison circuit which compares a first output voltage which is in proportion to the first current with a second output voltage which is in proportion to the second current, and outputs a control signal used to detect the first voltage signal based on a comparison result.

10. The signal level detector according to claim 9, wherein the first voltage signal is a differential signal, and the reference voltage signal includes two reference voltages.

11. The signal level detector according to claim 9, further comprising a first capacitance element and a second capacitance element respectively connected between an output terminal of the first squaring circuit and a ground potential and between an output terminal of the second squaring circuit and the ground potential.

12. The signal level detector according to claim 9, further comprising a first resistance element and a second resistance element respectively connected between an output terminal of the first squaring circuit and a ground potential and an output terminal of the second squaring circuit and the ground potential.

13. The signal level detector according to claim 9, wherein an output terminal of the first squaring circuit and an output terminal of the second squaring circuit are directly connected with each other and form one output end.

14. The signal level detector according to claim 13, wherein the first current is a charging current which flows out from the output terminal, and the second current is a discharging current which flows into the output terminal.

15. The signal level detector according to claim 13, wherein the first current is a discharging current which flows into the output terminal, and the second current is a charging current which flows out from the output terminal.

16. An amplification factor control system comprising:
a signal level detector which includes a first voltage/current conversion circuit which outputs a first current which depends on a voltage amplitude of an inputted signal, a second voltage/current conversion circuit which outputs a second current which depends on an inputted reference voltage signal, and a comparison circuit which compares the first current with the second current and outputs a control signal based on a comparison result; and
an amplification circuit to which the control signal of the signal level detector is inputted, and which outputs an output signal obtained by amplifying an inputted reception signal with an amplification factor according to the control signal and determines the output signal as the detection signal which is inputted to the signal level detector.

17. The amplification factor control system according to claim 16, wherein the first voltage/current conversion circuit outputs the first current which depends on a square of a voltage amplitude of the inputted signal, and the second voltage/current conversion circuit outputs the second current which depends on a square of an amplitude of the inputted reference voltage signal.

18. The amplification factor control system according to claim 16, wherein the control signal has a third voltage when the output signal from the amplification circuit is a first voltage having a first amplitude, and the control signal has a fourth voltage larger than the third voltage when the output signal from the amplification circuit is a second voltage having a second amplitude larger than the first amplitude.

19. The amplification factor control system according to claim 16, wherein the control signal has a third voltage when the output signal from the amplification circuit is a first voltage having a first amplitude, and the control signal has a fourth voltage smaller than the third voltage when the output signal from the amplification circuit is a second voltage having a second amplitude larger than the first amplitude.

20. The amplification factor control system according to claim 16, further comprising a capacitance element connected between a terminal to which the control signal is applied and a ground potential.
